(19) United States
(12) Patent Application Publication
(10) Pub. No.: US 2026/0313883 A1
(43) Pub. Date: Oct. 8, 2026

(54) SEMICONDUCTOR MEMORY DEVICE

(71) Applicant: SAMSUNG ELECTRONICS CO., LTD., Suwon-si (KR)

(72) Inventors: Yujin Kim, Suwon-si (KR); Jinwoo Han, Suwon-si (KR); Juhyun Kim, Suwon-si (KR); Hyeoncheol Kim, Suwon-si (KR)

(73) Assignee: SAMSUNG ELECTRONICS CO., LTD., Suwon-si (KR)

(21) Appl. No.: 19/629,227

(22) Filed: Mar. 26, 2026

(30) Foreign Application Priority Data
Apr. 2, 2025 (KR) 10-2025-0043051

(51) Int. Cl. H10B 12/00

(52) U.S. Cl. CPC H10B 12/488; H10B 12/02

(57) ABSTRACT

A semiconductor memory device includes a substrate including a stack region and a pad region arranged in a first horizontal direction, a first word line and a second word line arranged at a same vertical level, extending in the first horizontal direction in the stack region and the pad region, and spaced apart in a second horizontal direction intersecting the first horizontal direction, a plurality of bit lines extending in a vertical direction in the stack region and spaced apart in the first horizontal direction, a plurality of memory cells in the stack region, a word line pad between the first word line and the second word line in the pad region, and a word line contact extending in the vertical direction on the word line pad.

### CROSS-REFERENCE TO RELATED APPLICATION

This application is based on and claims priority under 35 U.S.C. § 119 to Korean Patent Application No. 10-2025-0043051, filed on Apr. 2, 2025, in the Korean Intellectual Property Office, the disclosure of which is incorporated by reference herein in its entirety.

### BACKGROUND

The disclosure relates to a semiconductor memory device, and more particularly, to a three-dimensional (3D) semiconductor memory device including a plurality of memory cells which are three-dimensionally arranged.

To meet the demand for miniaturized, multifunctional, and high-performance electronic products, high-capacity semiconductor memory devices are required. To provide high-capacity semiconductor memory devices, an increased integration density is necessary. As the integration density of two-dimensional (2D) semiconductor memory devices of the related art is determined based on the area occupied by a unit memory cell, the integration density of 2D semiconductor memory devices is increasing but is still limited. Therefore, 3D semiconductor memory devices have been proposed where a memory capacity increases by vertically stacking a plurality of memory cells on a substrate.

### SUMMARY

The disclosure provides a three-dimensional (3D) semiconductor memory device in which the integration density is increased.

The object of the disclosure is not limited to the aforesaid, but other objects not described herein will be clearly understood by those of ordinary skill in the art from descriptions below.

A semiconductor memory device according to an embodiment includes a substrate including a stack region and a pad region arranged in a first horizontal direction, a first word line and a second word line arranged at a same vertical level, extending in the first horizontal direction in the stack region and the pad region, and spaced apart in a second horizontal direction intersecting the first horizontal direction, a plurality of bit lines extending in a vertical direction in the stack region and spaced apart in the first horizontal direction, a plurality of memory cells in the stack region, a word line pad between the first word line and the second word line in the pad region, and a word line contact extending in the vertical direction on the word line pad.

A semiconductor memory device according to an embodiment includes a substrate including a stack region and a pad region arranged in a first horizontal direction, a first word line stack including a plurality of first word lines each extending in the first horizontal direction in the stack region and the pad region and stacked in a vertical direction, a second word line stack spaced apart from the first word line stack in a second horizontal direction intersecting the first horizontal direction and including a plurality of second word lines each extending in the first horizontal direction in the stack region and the pad region and stacked in a vertical direction, a plurality of bit lines extending in the vertical direction in the stack region and spaced apart in the first horizontal direction, and a plurality of word line pads between the first word line stack and the second word line stack in the pad region and spaced apart in the vertical direction and the first horizontal direction.

A semiconductor memory device according to an embodiment includes a substrate including a stack region and a pad region arranged in a first horizontal direction, a first word line stack including a plurality of first word lines each extending in the first horizontal direction in the stack region and the pad region and stacked in a vertical direction, a second word line stack spaced apart from the first word line stack in a second horizontal direction intersecting the first horizontal direction and including a plurality of second word lines each extending in the first horizontal direction in the stack region and the pad region and stacked in the vertical direction, a plurality of bit lines extending in the vertical direction in the stack region and spaced apart from one another in the first horizontal direction, a plurality of memory cells in the stack region and including a cell transistor and an information storage element, a plurality of word line pads arranged in the first horizontal direction to have different vertical levels, between the first word line stack and the second word line stack in the pad region, and a plurality of word line contacts extending in the vertical direction on the plurality of word line pads, each word line contact including a plurality of contact portions spaced apart in the second horizontal direction, wherein a width of each of the plurality of word line pads in the first horizontal direction is less than a width of each word line pad in the second horizontal direction.

A method of manufacturing a semiconductor memory device according to an embodiment includes an operation of forming a substrate including a stack region and a pad region arranged in a first horizontal direction, an operation of forming a first word line stack, a second word line stack, a plurality of bit lines extending in a vertical direction in the stack region and spaced apart from each other in the first horizontal direction, and a plurality of memory cells in the stack region, on a substrate, and an operation of forming a plurality of word line contacts extending in the vertical direction between the first word line stack and the second word line stack in the pad region and a plurality of word line pads which have different vertical levels and are spaced apart from one another in the first horizontal direction between the first word line stack and the second word line stack, wherein the first word line stack includes a plurality of first word lines which extend in the first horizontal direction and are stacked in the vertical direction, and the second word line stack are adjacent to the first word line stack in a second horizontal direction intersecting the first horizontal direction and includes a plurality of word lines which extend in the first horizontal direction and are stacked in the vertical direction.

The operation of forming the plurality of word line contacts may form a plurality of through holes to pass through an insulation structure between the first word line stack and the second word line stack.

The plurality of through holes having different depths may be arranged in the first horizontal direction between the first word line stack and the second word line stack.

The plurality of through holes having the same depth may be arranged in the second horizontal direction between the first word line stack and the second word line stack.

The operation of forming the plurality of word line pads may implant, through the through hole, a material for forming the plurality of word line pads.

A width of each of the plurality of word line pads in the first horizontal direction may be less than a width of each word line pad in the second horizontal direction.

A width of each of the plurality of word line pads in the second horizontal direction may be equal to a distance between the first word line stack and the second word line stack in the second horizontal direction.

### BRIEF DESCRIPTION OF DRAWINGS

Embodiments will be more clearly understood from the following detailed description taken in conjunction with the accompanying drawings in which:

FIG. 1 is an equivalent circuit diagram illustrating a stack cell array of a semiconductor memory device according to an embodiment;

FIG. 2 is a block diagram illustrating a semiconductor memory device according to an embodiment;

FIG. 3 is a perspective view illustrating a semiconductor memory device according to an embodiment;

FIG. 4 is a perspective view schematically illustrating a pad region of a semiconductor memory device according to an embodiment;

FIG. 5 is a plan view schematically illustrating a pad region of a semiconductor memory device according to an embodiment;

FIG. 6 is a perspective view illustrating a semiconductor memory device according to an embodiment;

FIGS. 7A, 7B, and 7C are plan views illustrating the arrangement of a semiconductor memory device according to an embodiment;

FIG. 8A is a perspective view illustrating a portion of a semiconductor memory device according to an embodiment;

FIG. 8B is a cross-sectional view illustrating a portion of a semiconductor memory device according to an embodiment;

FIG. 9 is a cross-sectional view illustrating a portion of a semiconductor memory device according to an embodiment;

FIG. 10 is an equivalent circuit diagram illustrating a memory cell array of a semiconductor memory device according to an embodiment;

FIG. 11A is a perspective view illustrating a portion of a semiconductor memory device according to an embodiment;

FIG. 11B is a cross-sectional view illustrating a portion of a semiconductor memory device according to an embodiment;

FIG. 12 is a plan view illustrating the arrangement of a semiconductor memory device according to an embodiment;

FIG. 13 is a plan view illustrating the arrangement of a semiconductor memory device according to an embodiment; and

FIGS. 14A, 14B, 14C, and 14D are cross-sectional views for describing a method of manufacturing a semiconductor memory device, according to an embodiment.

### DETAILED DESCRIPTION

Hereinafter, embodiments will be described in detail with reference to the accompanying drawings. Like reference numerals refer to like elements in the drawings, and their redundant descriptions are omitted.

In embodiments, the terms “first” and “second” may be used for differentiating one element from another element, instead of a limited meaning. In embodiments, a singular form of elements may include a plural form unless another case is clearly designated in context.

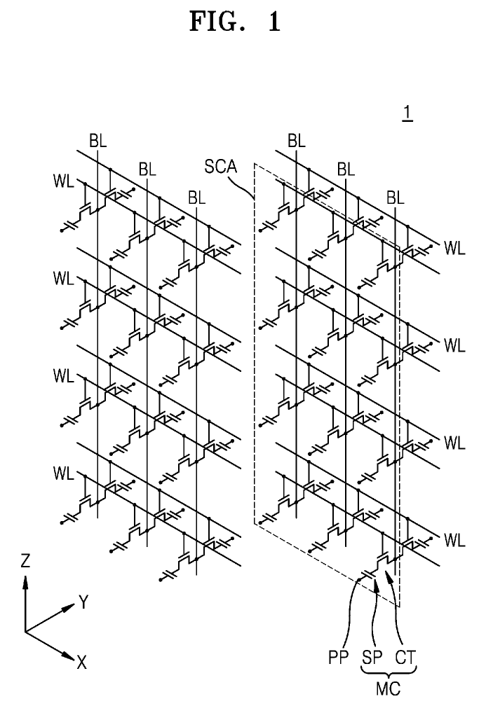

FIG. 1 is an equivalent circuit diagram illustrating a stack cell array of a semiconductor memory device according to an embodiment.

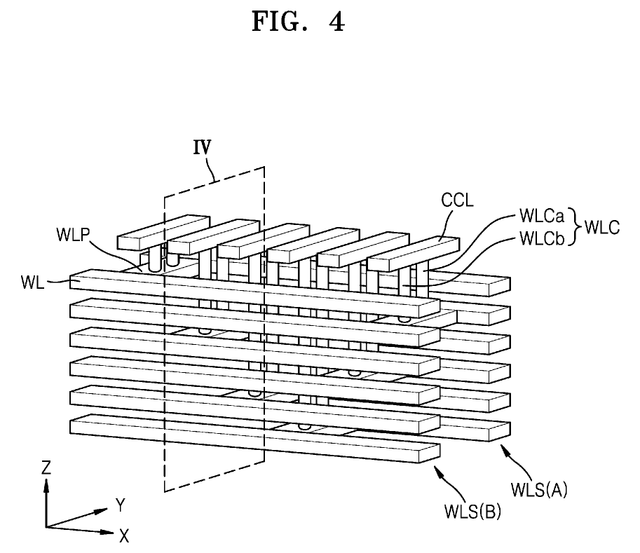

Referring to FIG. 1, a memory cell array 1 of a semiconductor memory device according to an embodiment may include a plurality of sub cell arrays SCA. Each of the plurality of sub cell arrays SCA may include a plurality of bit lines BL, a plurality of word lines WL, and a plurality of memory cells MC. Each of the plurality of memory cells MC may include a cell transistor CT and an information storage element SP. The cell transistor (e.g., single cell transistor) CT may be disposed between the word line (e.g., single word line) WL and the bit line (e.g., single bit line) BL. The information storage element SP may be a memory element which stores data. The information storage element SP may be a memory element using a capacitor, a memory element using a magnetic tunnel junction pattern, or a memory element using a variable resistor including a phase-change material. In some embodiments, the memory cell MC may be dynamic random-access memory (DRAM), the information storage element SP may be a capacitor, and a detailed example thereof will be described below with reference to FIG. 4C.

The word line WL may be a conductive pattern (for example, a word line), which is apart from a substrate and is disposed on/above the substrate. The plurality of word lines WL may extend in a first horizontal direction (e.g., X-axis direction). Word lines WL of the sub cell array (e.g., single sub cell array) SCA may be apart from one another in a vertical direction (e.g., Z-axis direction). The bit line BL may extend in the vertical direction (e.g., Z-axis direction) from the substrate. Bit lines BL of the sub cell array SCA may be apart from one another in the first horizontal direction (e.g., X-axis direction).

In the memory cell array 1, the plurality of word lines WL may extend in the first horizontal direction (e.g., X-axis direction) and may be apart from one another in each of a second horizontal direction (e.g., Y-axis direction) and the vertical direction (e.g., Z-axis direction). In the memory cell array 1, the plurality of bit lines BL may extend in the vertical direction (e.g., Z-axis direction) and may be apart from one another in each of the first horizontal direction (e.g., X-axis direction) and the second horizontal direction (e.g., Y-axis direction). The plurality of sub cell arrays SCA may be arranged in the second horizontal direction (e.g., Y-axis direction). The second horizontal direction (e.g., Y-axis direction) may be perpendicular to the first horizontal direction (e.g., X-axis direction).

A gate of the cell transistor CT may be connected to a word line WL, and a source region of the cell transistor CT may be connected to a bit line BL. The information storage element SP may be connected to a drain region of the cell transistor CT. In some embodiments, the information storage element SP may be a capacitor, which includes a first electrode, a second electrode, and a capacitor dielectric layer disposed between the first electrode and the second electrode, the first electrode of the capacitor may be connected to the drain region of the cell transistor CT, and the second electrode of the capacitor may be connected to a ground wiring PP.

The memory cell array 1 of the semiconductor memory device may include the plurality of sub cell arrays SCA each including the plurality of memory cells MC which are arranged apart from one another in each of the first horizontal direction (e.g., X-axis direction) and the vertical direction (e.g., Z-axis direction) to configure a row and a column, the plurality of bit lines BL which are connected to the cell transistors CT of the memory cells MC arranged in the vertical direction (e.g., Z-axis direction) and are arranged apart from one another in the first horizontal direction (e.g., X-axis direction) to extend in the vertical direction (e.g., Z-axis direction), and the plurality of word lines WL which are arranged apart from one another in the vertical direction (e.g., Z-axis direction) to extend in the first horizontal direction (e.g., X-axis direction), and the plurality of sub cell arrays SCA may be arranged in the second horizontal direction (e.g., Y-axis direction). The semiconductor memory device may include a plurality of memory cell arrays 1.

The first horizontal direction (e.g., X-axis direction), the second horizontal direction (e.g., Y-axis direction), and the vertical direction (e.g., Z-axis direction) may be respectively referred to as a first direction, a second direction, and a third direction. In another example, the first horizontal direction (e.g., X-axis direction), the vertical direction (e.g., Z-axis direction), and the second horizontal direction (e.g., Y-axis direction) may be respectively referred to as a first direction, a second direction, and a third direction. The first direction, the second direction, and the third direction may be perpendicular to one another.

Two sub cell arrays SCA adjacent to each other in the second horizontal direction (e.g., Y-axis direction) may share the bit lines BL. Source regions of the cell transistors CT included in each of the two sub cell arrays SCA may be connected to the bit lines BL shared by the two sub cell arrays SCA. From each of the bit lines BL shared by the two sub cell arrays SCA, the information storage element SP and the source region and the drain region of the cell transistor CT of each of the two sub cell arrays SCA may be arranged in directions opposite to each other. For example, the information storage element SP and the source region and the drain region of the cell transistor CT of the sub cell array SCA connected to the bit line BL shared by the two sub cell arrays SCA may be sequentially arranged in the second horizontal direction (e.g., Y-axis direction), and the information storage element SP and the source region and the drain region of the cell transistor CT of the other sub cell array SCA may be arranged in a direction opposite to the second horizontal direction (e.g., Y-axis direction). For example, the two memory cells MC may be disposed in the second horizontal direction (e.g., Y-axis direction) at the same vertical level, between a pair of bit lines BL sequentially arranged adjacent to each other in the second horizontal direction (e.g., Y-axis direction) among the plurality of bit lines BL.

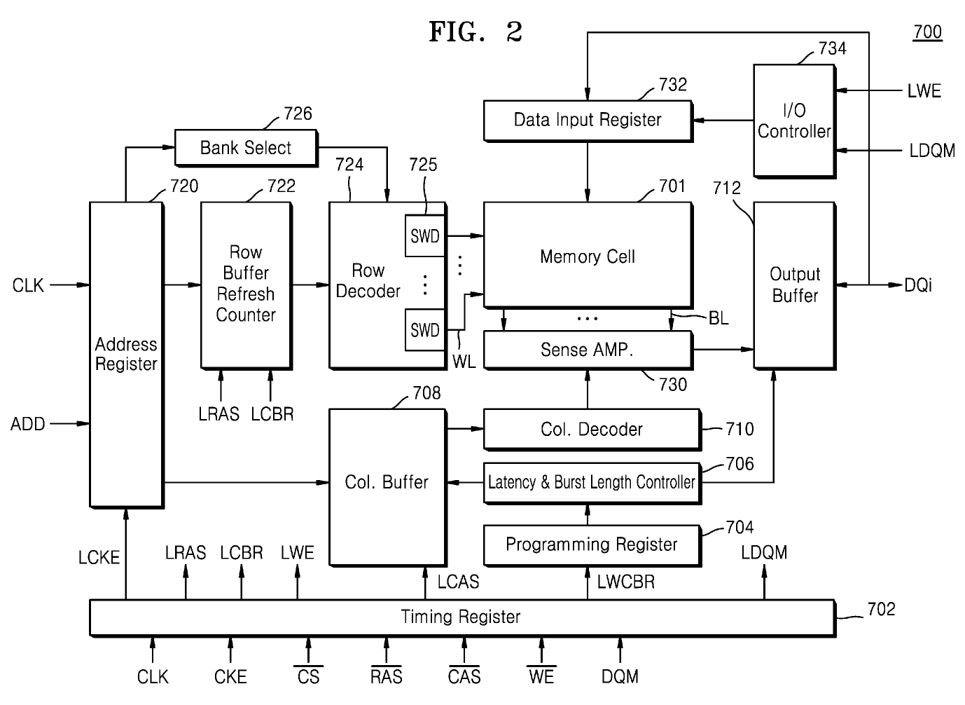

FIG. 2 is a block diagram illustrating a semiconductor memory device 700 according to an embodiment.

Referring to FIG. 2, the semiconductor memory device 700 may include the memory cell array 701, including DRAM cells which are memory cells, and various circuit blocks for driving the DRAM cell. For example, a timing register 702 may be activated when a chip selection signal CSB shifts from a non-active level (for example, logic high) to an active level (for example, logic low). The timing register 702 may receive external command signals such as a clock signal CLK, a clock enable signal CKE, a chip selection signal CSB, a row address strobe signal RASB, a column address strobe signal CASB, a write enable signal WEB, and a data input/output (I/O) mask signal DQM from the outside. The timing register 702 may process the received external command signals to generate various internal command signals LRAS, LCBR, LWE, LCAS, LWCBR, and LDQM for controlling the circuit blocks.

Some internal command signals generated by the timing register 702 may be stored in a programming register 704. For example, latency information or burst length information associated with a data output may be stored in the programming resister 704. The internal command signals stored in the programming register 704 may be provided to a latency and burst length controller 706. The latency and burst length controller 706 may provide a control signal, which is for controlling the latency and/or burst length of a data output, to a column decoder 710 or an output buffer 712 through a column address buffer 708.

An address register 720 may receive the clock signal CLK and an address signal ADD from the outside. A row address signal may be provided to a row decoder 724 through a row address buffer 722. For example, a column address signal may be provided to the column decoder 710 through the column address buffer 708. The row address buffer 722 may further receive a refresh address signal generated by a refresh counter in response to refresh commands LRAS and LCBR and may provide either the row address signal or the refresh address signal to the row decoder 724. For example, the address register 720 may provide a bank selector 726 with a bank signal for selecting a bank.

The row decoder 724 may decode the row address signal or the refresh address signal input to the row address buffer 722. The row decoder 724 may include a plurality of sub word line drivers 725. The plurality of sub word line drivers 725 may activate a word line WL of the memory cell array 701. The plurality of sub word line drivers 725 may be disposed adjacent to the memory cell array 701 and arranged at certain intervals along a side of the row decoder 724. For example, the plurality of sub word line drivers 725 may be disposed adjacent to a first side (e.g., left side) of the memory cell array 701, and a sense amplifier 730 may be disposed adjacent to a second side (e.g., bottom side) of the memory cell array 701.

The column decoder 710 may decode the column address signal and may perform a selection operation on a bit line BL of the memory cell array 701. For example, a column selection line may be applied to the semiconductor memory device 700, and thus, a selection operation may be performed through the column selection line.

The sense amplifier 730 may amplify data of the memory cell MC of the memory cell array 701, which is selected by the row decoder 724 and the column decoder 710, and may provide the amplified data to the output buffer 712. Data for writing into the memory cell may be provided to the memory cell array 701 through a data input register 732, and an I/O controller 734 may control a data transfer operation through the data input register 732.

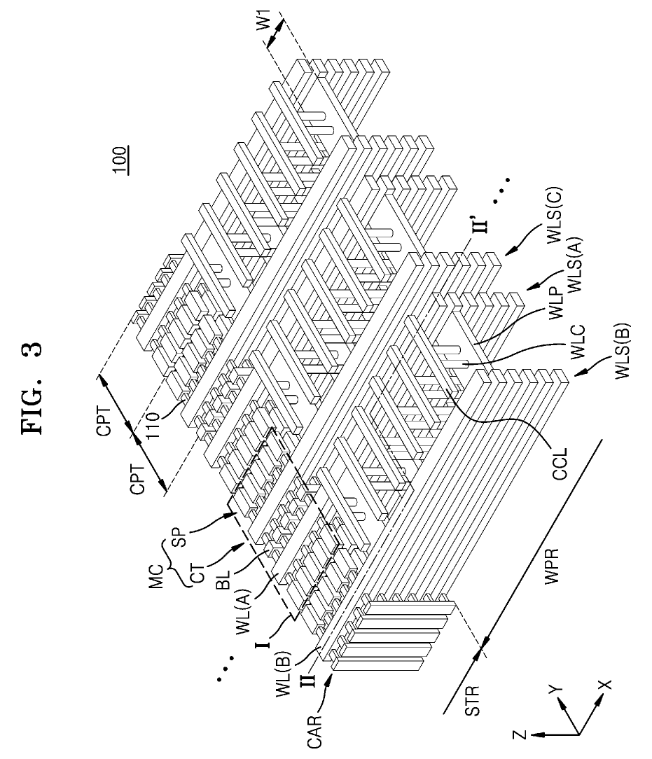

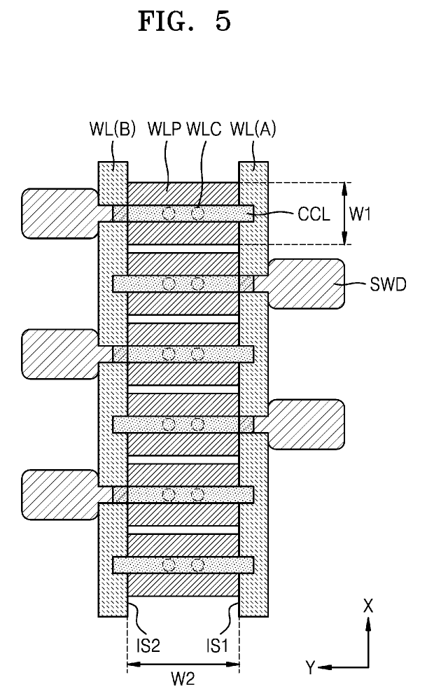

FIG. 3 is a perspective view illustrating a semiconductor memory device according to an embodiment. FIG. 4 is a perspective view schematically illustrating a pad region of a semiconductor memory device according to an embodiment. FIG. 5 is a plan view schematically illustrating a pad region of a semiconductor memory device according to an embodiment.

Referring to FIG. 3, a semiconductor memory device 100 according to an embodiment may include a stack region STR and a pad region WPR. A stack cell array structure CAR may be disposed in the stack region STR. The stack region STR and the pad region WPR may be arranged in the first horizontal direction (e.g., X-axis direction). For convenience of illustration, FIG. 3 illustrates a single stack region STR and a single pad region WPR, but in some embodiments, the semiconductor memory device 100 may include a plurality of stack regions STR and a plurality of pad regions WPR that are alternately arranged in the first horizontal direction (e.g., X-axis direction).

The stack cell array structure CAR may include a plurality of sub cell arrays SCA (see FIG. 1). The plurality of sub cell arrays SCA included in a single stack cell array structure CAR may be arranged in the second horizontal direction (e.g., Y-axis direction). Each of the plurality of sub cell arrays SCA may include a plurality of bit lines BL, a plurality of word lines WL, and a plurality of memory cells MC. Each of the plurality of memory cells MC may include a cell transistor CT and an information storage element SP. The cell transistor CT may include a semiconductor pattern 110. In some embodiments, the semiconductor pattern 110 may extend in the second horizontal direction (e.g., Y-axis direction). The semiconductor pattern 110 may include a source region and a drain region. The source region and the drain region may be disposed at end portions (e.g., opposite end portions) of the semiconductor pattern 110 in the second horizontal direction (e.g., Y-axis direction).

The plurality of word lines WL may extend in the first horizontal direction (e.g., X-axis direction). In the stack cell array structure CAR, the plurality of word lines WL may extend in the first horizontal direction (e.g., X-axis direction) and may be apart from one another in each of the second horizontal direction (e.g., Y-axis direction) and the vertical direction (e.g., Z-axis direction). Word lines WL of the single sub cell array SCA may be apart from one another in the vertical direction (e.g., Z-axis direction). The plurality of word lines WL may extend in the first horizontal direction (e.g., X-axis direction) in the stack region STR and the pad region WPR.

Two word lines WL, which are disposed at the same vertical level and are adjacent to each other in the second horizontal direction (e.g., Y-axis direction), may be respectively referred to as a first word line WL(A) and a second word line WL(B). A plurality of first word lines WL(A) overlapping in the vertical direction (e.g., Z-axis direction) among the plurality of word lines WL may be defined as a first word line stack WLS(A), and a plurality of second word lines WL(B) overlapping in the vertical direction (e.g., Z-axis direction) among the plurality of word lines WL may be defined as a second word line stack WLS(B).

The bit line BL may extend in the vertical direction (e.g., Z-axis direction) from the substrate. In the stack cell array structure CAR, the plurality of bit lines BL may extend in the vertical direction (e.g., Z-axis direction) and may be apart from one another in each of the first horizontal direction (e.g., X-axis direction) and the second horizontal direction (e.g., Y-axis direction). Bit lines BL of the single sub cell array SCA (see FIG. 1) may be apart from one another in the first horizontal direction (e.g., X-axis direction). For example, the plurality of bit lines BL may include bit line columns in which bit lines BL are arranged apart from one another to form a column in the first horizontal direction (e.g., X-axis direction), and the bit line columns may be arranged apart from one another in the second horizontal direction (e.g., Y-axis direction). In some embodiments, one bit line column and a pair of word lines WL may be repeatedly arranged one-dimensionally in the second horizontal direction (e.g., Y-axis direction).

The cell transistor (e.g., single cell transistor) CT may be disposed between the word line (e.g., single word line) WL and the bit line (e.g., single bit line) BL. The information storage element SP may be connected to the cell transistor CT. The information storage element SP may be a memory element for storing data. The gate of the cell transistor CT may be connected to the word line WL, and the source region of the cell transistor CT may be connected to the bit line BL. The information storage element SP may be connected to the drain region of the cell transistor CT.

In some embodiments, the source region and the drain region of the cell transistor CT and the information storage element SP may be arranged in the second horizontal direction (e.g., Y-axis direction) from the bit line BL connected to the source region of the cell transistor CT. The source region and the drain region of the cell transistor CT, connected to each of two bit lines BL adjacent to each other in the second horizontal direction (e.g., Y-axis direction), and the information storage element SP may be arranged in directions opposite to each other. For example, the source region and the drain region of the cell transistor CT, connected to one bit line (e.g., selected bit line) BL among the two bit lines BL adjacent to each other in the second horizontal direction (e.g., Y-axis direction), and the information storage element SP may be sequentially arranged in the second horizontal direction (e.g., Y-axis direction), and the source region and the drain region of the cell transistor CT, connected to the other bit line BL, and the information storage element SP may be arranged in a direction opposite to the second horizontal direction (e.g., Y-axis direction).

According to various embodiments, the word line pad WLP may be disposed between the first word line WL(A) and the second word line WL(B) each disposed in the pad region WPR. A side of the word line pad WLP in the second horizontal direction (e.g., Y-axis direction) may be connected to the first word line WL(A), and the other side of the word line pad WLP in the second horizontal direction (e.g., Y-axis direction) may be connected to the second word line WL(B). The side of the word line pad WLP in the second horizontal direction (e.g., Y-axis direction) may contact the first word line WL(A), and the other side of the word line pad WLP in the second horizontal direction (e.g., Y-axis direction) may contact the second word line WL(B). The word line pad WLP may contact a side surface of the first word line WL(A) and may contact a side surface of the second word line WL(B). The word line pad WLP may be connected (e.g., electrically connected) to the first word line WL(A) and the second word line WL(B).

As shown in FIG. 3, the word line pad WLP, the first word line WL(A), and the second word line WL(B) may be disposed at the same vertical level, but an embodiment is not limited thereto. For example, the word line pad WLP may have a lower surface contacting a lower surface of the first word line WL(A) and a lower surface of the second word line WL(B), and the word line pad WLP may have an upper surface contacting an upper surface of the first word line WL(A) and an upper surface of the second word line WL(B).

Referring to FIGS. 3 to 5. the word line contact WLC may be disposed on the word line pad WLP. The word line contact WLC may extend in the vertical direction (e.g., Z-axis direction) on the word line pad WLP. The word line contact WLC may connect (e.g., electrically connect) the word line pad WLP to a sub word line driver SWD.

The word line contact WLC may include a plurality of contact portions which are apart from each other. For example, the plurality of contact portions of the word line contact WLC may include a first contact portion WLCa and a second contact portion WLCb, which extend in the vertical direction (e.g., Z-axis direction) on the word line pad WLP. Lengths of the first contact portion WLCa and the second contact portion WLCb in the vertical direction (e.g., Z-axis direction) may be equal to each other. The first contact portion WLCa and the second contact portion WLCb may be arranged apart from each other in a direction in which the first word line WL(A) and the second word line WL(B) are apart from each other. For example, the first contact portion WLCa and the second contact portion WLCb may be arranged apart from each other in the second horizontal direction (e.g., Y-axis direction). The arrangement of the plurality of contact portions of the word line contact WLC according to an embodiment is not limited thereto. For example, the plurality of contact portions of the word line contact WLC may include a third contact portion and a fourth contact portion, which extend in the vertical direction (e.g., Z-axis direction) on the word line pad WLP and are arranged in the first horizontal direction (e.g., X-axis direction). In another example, the word line contact WLC may include only one contact portion.

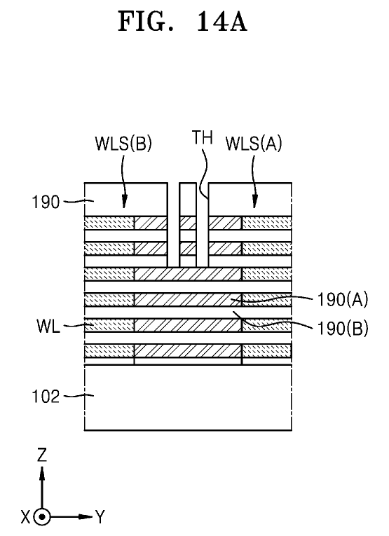

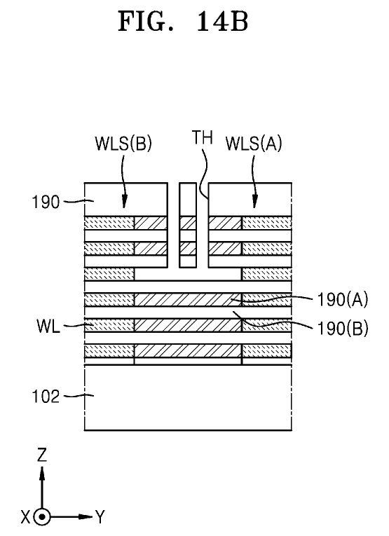

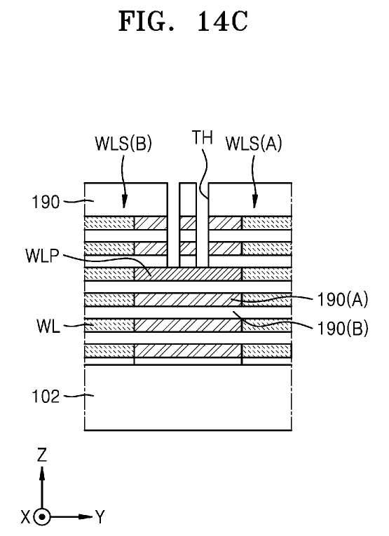

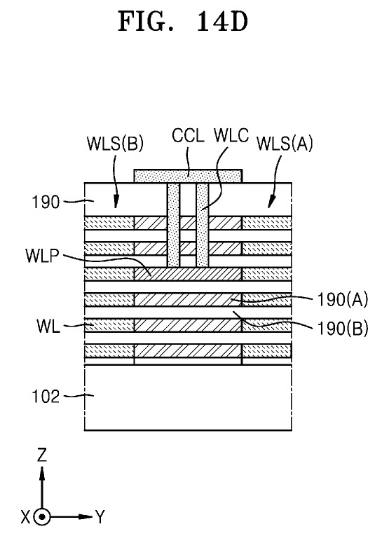

According to an embodiment, because the word line contact WLC includes the plurality of contact portions which include the first contact portion WLCa and the second contact portion WLCb, the shape and width of the word line pad WLP may be adjusted. According to an embodiment, the word line pad WLP may be formed by implanting a material through a through hole (e.g., TH of FIG. 14A) (corresponding to the plurality of contact portions) which is formed during the operation of forming the word line contact WLC, and the number and positions of through holes (e.g., TH of FIG. 14A) (corresponding to the plurality of contact portions) may be adjusted to modify the shape of the word line pad WLP.

In an embodiment, a contact connection wiring CCL connecting the plurality of contact portions of the word line contact WLC with each other may be disposed on the word line contact WLC. For example, the contact connection wiring CCL may be connected to the first contact portion WLCa and the second contact portion WLCb and may extend in the second horizontal direction (e.g., Y-axis direction).

The word line pad WLP may be connected to the sub word line driver SWD through the word line contact WLC and/or the contact connection wiring CCL. Referring to FIG. 5, it is illustrated that the sub word line driver SWD contacts the contact connection wiring CCL, but embodiments are not limited thereto. For example, a wiring and/or a contact instead of the contact connection wiring CCL may be disposed between the word line contact WLC and the sub word line driver SWD and may connect (e.g., electrically connect) the word line contact WLC to the sub word line driver SWD.

The sub word line driver SWD may activate a word line WL connected to the memory cell MC to select the memory cell MC along with the bit line BL. For example, the sub word line driver SWD may activate the first word line WL(A) through the word line pad WLP to select one memory cell MC from among the memory cells MC connected to the first word line WL(A) along with a corresponding bit line BL among the plurality of bit lines BL and may activate the second word line WL(B) through the word line pad WLP to select one memory cell MC from among the memory cells MC connected to the second word line WL(B) along with a corresponding bit line BL among the plurality of bit lines BL. Therefore, the first word line WL(A) and the second word line WL(B) each connected to the word line pad (e.g., single word line pad) WLP may share the word line pad (e.g., single word line pad) WLP and the word line contact WLC and the sub word line driver SWD each connected to the word line pad WLP. The first word line WL(A) and the second word line WL(B) each connected to the word line pad (e.g., single word line pad) WLP may be driven by the sub word line driver (e.g., single sub word line driver) SWD.

Referring to FIG. 5, the sub word line driver SWD may be provided in plurality. The plurality of sub word line drivers SWD that are alternately disposed at the first word line WL(A) side and the second word line WL(B) side in the first horizontal direction (e.g., X-axis direction). The first word line WL(A) side may denote a position closer to the first word line WL(A) than the second word line WL(B), and the second word line WL(B) side may denote a position closer to the second word line WL(B) than to the first word line WL(A). As shown in FIG. 5, because the plurality of sub word line drivers SWD are alternately disposed at the first word line WL(A) side and the second word line WL(B) side, a wiring design may be facilitated, but embodiments are not limited thereto, and the plurality of sub word line drivers SWD may be disposed at selected positions based on the design.

Referring to FIGS. 3 to 5, the word line pad WLP may be provided in plurality. The plurality of word line pads WLP may be disposed between the first word line stack WLS(A) and the second word line stack WLS(B). Each of the plurality of word line pads WLP may be connected between one first word line WL(A) selected among the plurality of first word lines WL(A) included in the first word line stack WLS(A) and one second word line WL(B) selected among the plurality of second word lines WL(B) included in the second word line stack WLS(B). The selected first word line WL(A) and the selected second word line WL(B) may be disposed at the same vertical level.

To provide a different description, each of the plurality of word line pads WLP may be disposed between a word line pair (e.g., first word line WL(A) and second word line WL(B)) at different vertical levels. The plurality of word line pads WLP may be apart from each other in the vertical direction (e.g., Z-axis direction).

The number of word line pads WLP may be the same as the number of first word lines WL(A) included in the first word line stack WLS(A). The number of word line pads WLP may be the same as the number of second word lines WL(B) included in the second word line stack WLS(B).

The plurality of word line pads WLP may be arranged in a row (e.g., single row) in the first horizontal direction (e.g., X-axis direction). The plurality of word line pads WLP may be apart from one another in the first horizontal direction (e.g., X-axis direction). The plurality of word line pads WLP having different vertical levels may not overlap each other in the vertical direction (e.g., Z-axis direction). However, an embodiment is not limited thereto. For example, a region of the word line pad WLP selected among the plurality of word line pads WLP may overlap, in the vertical direction (e.g., Z-axis direction), another word line pad WLP adjacent to the selected word line pad WLP in the first horizontal direction (e.g., X-axis direction).

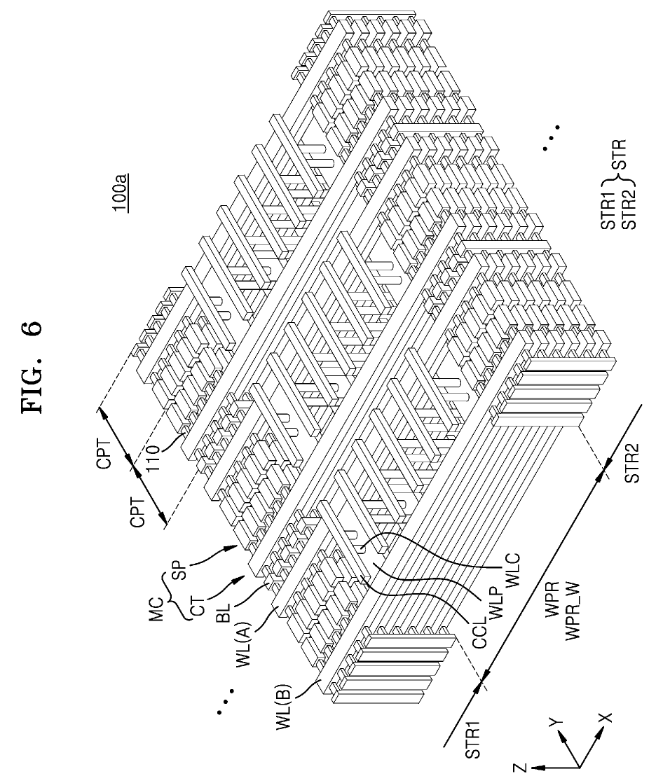

Referring to FIGS. 3 to 5, a width W1 of each of the plurality of word line pads WLP in the first horizontal direction (e.g., X-axis direction) may be less than a width W2 of each of the plurality of word line pads WLP in the second horizontal direction (e.g., Y-axis direction). In an embodiment, the width W1 of the word line pad WLP in the first horizontal direction (e.g., X-axis direction) may be less than a value (for example, the number of first word lines WL(A) included in the first word line stack WLS(A)) obtained by dividing a width (e.g., WPR_W of FIG. 6) of a pad region WPR in the first horizontal direction (e.g., X-axis direction) by the number of word lines WL overlapping each other in the vertical direction (e.g., Z-axis direction).

A width W2 of each of the plurality of word line pads WLP in the second horizontal direction (e.g., Y-axis direction) may be equal to a distance between the first word line WL(A) and the second word line WL(B) in the second horizontal direction (e.g., Y-axis direction). The distance between the first word line WL(A) and the second word line WL(B) in the second horizontal direction (e.g., Y-axis direction) may be defined at a distance between an inner surface IS1 of the first word line WL(A) facing the second word line WL(B) and an inner surface IS2 of the second word line WL(B) facing the first word line WL(A).

Referring to FIGS. 3 to 5, the word line pad WLP in the pad region WPR may overlap the information storage element SP of the stack region STR in the first horizontal direction (e.g., X-axis direction). The word line pad WLP may be disposed between two word lines adjacent to each other in the second horizontal direction (e.g., Y-axis direction) with the information storage element SP therebetween. For example, the first word line WL(A) and the second word line WL(B) may be apart from each other in the second horizontal direction (e.g., Y-axis direction) with the information storage element SP therebetween.

A third word line stack WLS(C), including a plurality of third word lines WL(C) which extend in the first horizontal direction (e.g., X-axis direction) and are stacked in the vertical direction (e.g., Z-axis direction), may be disposed in the pad region WPR. The third word line stack WLS(C) may be adjacent to the second word line stack WLS(B) in the second horizontal direction (e.g., Y-axis direction) with the bit line BL therebetween. The bit line BL may be one-dimensionally (or horizontally) disposed between the second word line stack WLS(B) and the third word line stack WLS(C).

A plurality of memory cells MC may be arranged to have a cell pitch CPT in the second horizontal direction (e.g., Y-axis direction). For example, when two sub cell arrays SCA (see FIG. 1) adjacent to each other in the second horizontal direction (e.g., Y-axis direction) share bit lines BL, the cell pitch CPT may be a length up to the center of the bit line BL in the second horizontal direction (e.g., Y-axis direction) from a portion between two information storage elements SP adjacent to each other in the second horizontal direction (e.g., Y-axis direction). In some embodiments, as in the semiconductor memory device illustrated in FIG. 1, when the two sub cell arrays SCA adjacent to each other in the second horizontal direction (e.g., Y-axis direction) do not share the bit line BL, the cell pitch CPT may be a length up to a portion between the two bit lines BL adjacent to each other in the second horizontal direction (e.g., Y-axis direction) from two information storage elements SP adjacent to each other in the second horizontal direction (e.g., Y-axis direction).

Generally, when a word line contact is disposed on a word line extending from a stack region to a pad region, it may be required that a thickness (e.g., a thickness in e.g., Y-axis direction) of a word line is formed to be relatively large for forming the word line contact, and thus, a cell pitch may increase. Moreover, the magnitude of parasitic capacitance between word lines may increase due to the large thickness of word lines overlapping each other in the vertical direction (e.g., Z-axis direction).

The semiconductor memory device according to various embodiments may include the word line contact WLC disposed on the word line pad WLP disposed between the first word line WL(A) and the second word line WL(B), in the pad region WPR. As described above, when the word line contact WLC is disposed on the word line pad WLP, a thickness of the first word line WL(A) and the second word line WL(B) in the second horizontal direction (e.g., Y-axis direction) may have a small size, and thus, a cell pitch CPT may decrease, and the integration density of the semiconductor memory device 100 may increase. When a thickness of the first word line WL(A) and the second word line WL(B) in the second horizontal direction (e.g., Y-axis direction) has a small size, a word line contact WLC may be formed between the first word line WL(A) and the second word line WL(B), and thus, the word line contact WLC may be readily formed.

Moreover, the thicknesses of the plurality of word lines WL overlapping each other in the vertical direction (e.g., Z-axis direction) may have a small size, and a plurality of word line pads WLP may be apart from each other in the first horizontal direction (e.g., X-axis direction), and thus, an area (or size) of metals overlapping each other in the vertical direction (e.g., Z-axis direction) may decrease, thereby reducing the magnitude of parasitic capacitance occurring in the pad region WPR.

For example, a single sub word line driver SWD may turn on two word lines WL together, through the word line pad WLP and a word line contact WLC. Accordingly, an available area (or size) where the sub word line driver SWD is disposed may increase.

Referring again to FIGS. 3 to 5, the word line contact WLC may be provided in plurality to be disposed on each of the plurality of word line pads WLP. The plurality of word line contacts WLC may be arranged in the same direction as the arrangement direction of the plurality of word line pads WLP. For example, the word line contact WLC may be arranged in the first horizontal direction (e.g., X-axis direction) between the first word line WL(A) and the second word line WL(B). Each of a plurality of word line contacts WLC disposed on different word line pads WLP may differ in length in the vertical direction (e.g., Z-axis direction).

FIG. 6 is a perspective view illustrating a semiconductor memory device 100a according to an embodiment. In FIG. 6, the same reference numerals as in FIG. 3 may refer to elements which are substantially the same as the elements described above with reference to FIG. 3, and thus, redundant descriptions may be omitted, and the difference therebetween will be described below.

Referring to FIG. 6, the semiconductor memory device 100a according to an embodiment may include the plurality of stack regions STR. The plurality of stack regions STR may include a first stack region STR1 and a second stack region STR2. A pad region WPR may be disposed between the first stack region STR1 and the second stack region STR2. For example, the first stack region STR1, the pad region WPR, and the second stack region STR2 may be arranged in the first horizontal direction (e.g., X-axis direction). For example, the first stack region STR1 may be adjacent to a side of the pad region WPR in the first horizontal direction (e.g., X-axis direction) and the second stack region STR2 may be adjacent to another side (e.g., opposite side) of the pad region WPR in the first horizontal direction (e.g., X-axis direction). The elements in the first stack region STR1 may be the same as the elements in the second stack region STR2.

Each of the first word line WL(A) and the second word line WL(B) may extend in the first horizontal direction (e.g., X-axis direction) to be disposed in the first stack region STR1, the pad region WPR, and the second stack region STR2. The word line pad WLP according to various embodiments may be connected to the first word line WL(A) and the second word line WL(B), and thus, the sub word line driver SWD (see FIG. 5) may select the memory cell MC disposed in each of the first stack region STR1 and the second stack region STR2 through a word line contact WLC and the word line pad WLP.

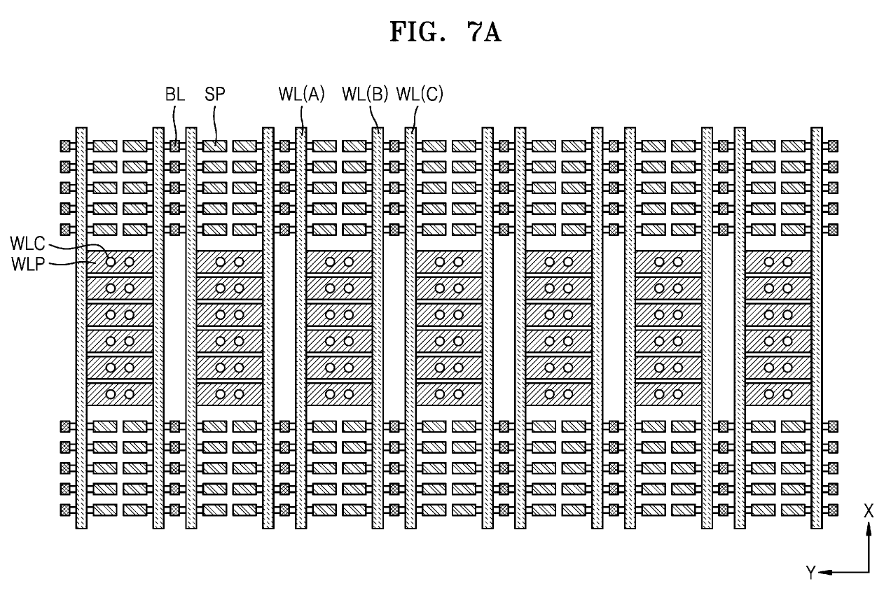

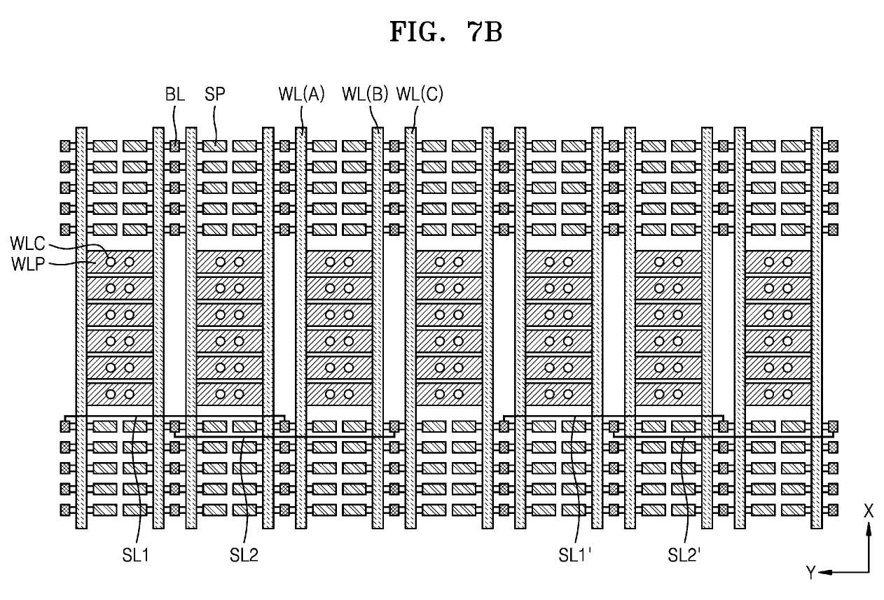

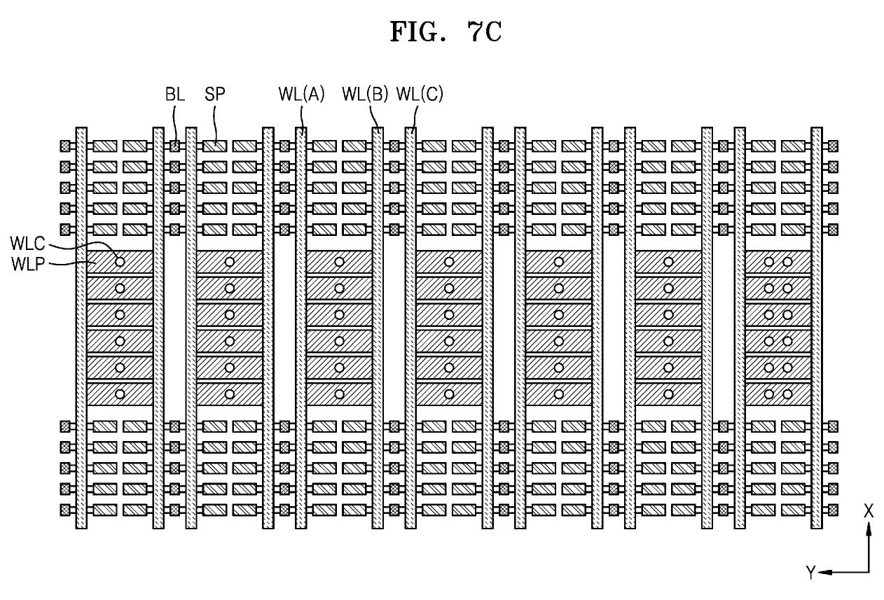

FIGS. 7A, 7B, and 7C are plan views illustrating the arrangement of a semiconductor memory device according to an embodiment.

Referring to FIG. 7A in conjunction with FIG. 3, the information storage element SP may be disposed between the first word line WL(A) and the second word line WL(B) each connected to the word line pad WLP. The first word line WL(A) and the second word line WL(B) each connected to the word line pad WLP may be respectively connected to different bit lines BL. The semiconductor memory device according to an embodiment may turn on the first word line WL(A) and the second word line WL(B), which do not share the bit line BL.

When the first word line WL(A) and the second word line WL(B) are driven together, it may be difficult to compare a signal of the bit line BL connected to the first word line WL(A) with a signal of the bit line BL connected to the second word line WL(B) to perform a sense amplifier operation. Therefore, in an embodiment, a sense amplifier operation of comparing the bit line signal and a complementary bit line signal may be performed by comparing a signal of the bit line BL connected to the first word line WL(A) with a signal of another bit line BL except for the bit line BL connected to the second word line WL(B). In another example, the sense amplifier operation may be performed by comparing a signal of the bit line BL connected to the second word line WL(B) with a signal of another bit line BL except for the bit line BL connected to the first word line WL(A).

Referring to FIG. 7B, the semiconductor memory device 100 according to an embodiment may include a strap wiring which connects, with each other, bit lines BL apart from each other in a second direction (e.g., Y-axis direction). The strap wiring may include a first strap wiring SL1 which connects, with each other, the bit line BL connected to the first word line WL(A) and another bit line BL except for the bit line BL connected to the second word line WL(B). The strap wiring may include a second strap wiring SL2 which connects, with each other, the bit line BL connected to the second word line WL(B) and another bit line BL except for the bit line BL connected to the first word line WL(A). The strap wiring may further include a third strap wiring SL1’, to which a complementary signal with respect to the first strap wiring SL1 is transferred, and a fourth strap wiring SL2’ to which a complementary signal with respect to the second strap wiring SL2 is transferred. The semiconductor memory device according to an embodiment may include a strap wiring which connects, with each other, bit lines BL apart from each other in the second direction (e.g., Y-axis direction), thereby reducing the number of sense amplifiers needed for an operation of the semiconductor memory device.

Referring to FIG. 7C in conjunction with FIG. 7A, in an embodiment, the single word line contact WLC disposed on the single word line pad WLP may include the single contact portion. As described above, the number, arrangement, and shape of contact portions of the word line contact WLC may be variously changed based on a design.

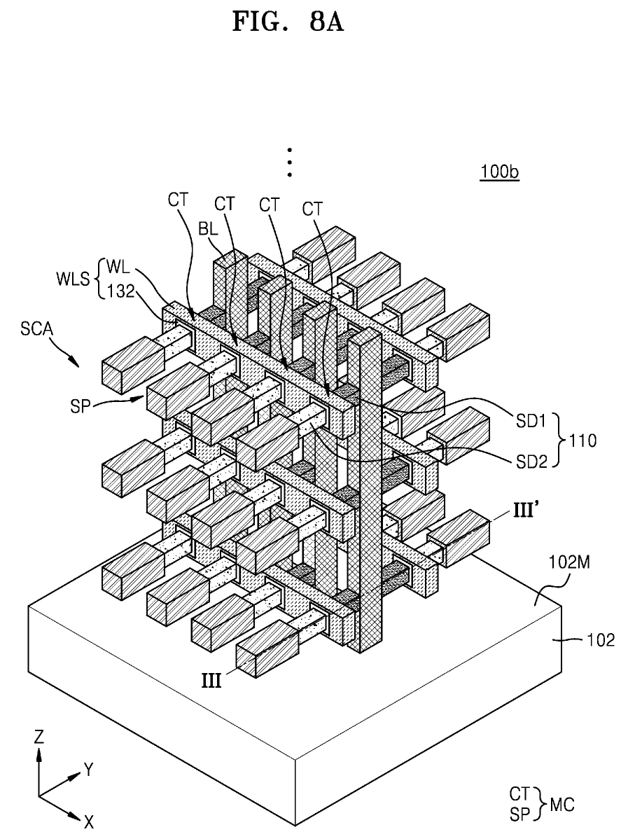

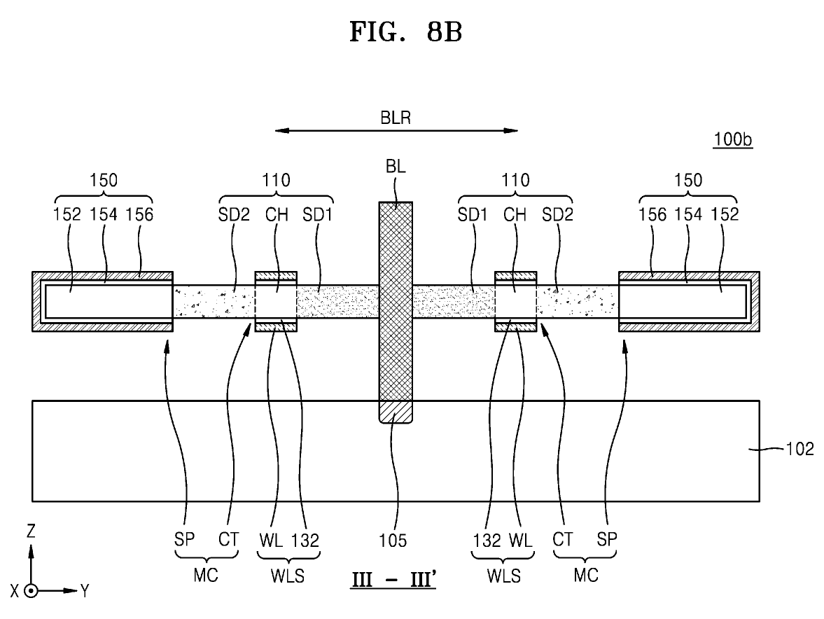

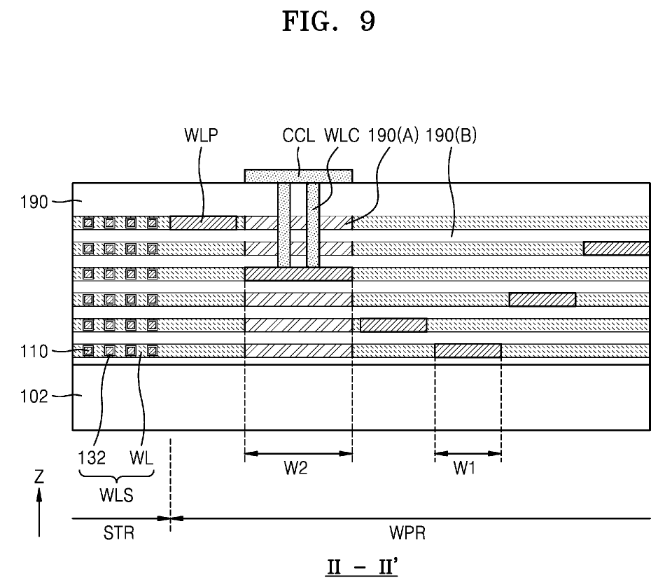

FIG. 8A is a perspective view illustrating a portion of a semiconductor memory device according to an embodiment, FIG. 8B is a cross-sectional view illustrating a portion of a semiconductor memory device according to an embodiment, and FIG. 9 is a cross-sectional view illustrating a portion of a semiconductor memory device according to an embodiment. In detail, FIG. 8A is a perspective view illustrating portion I of FIG. 3, FIG. 8B is a cross-sectional view taken along line Ⅲ-Ⅲ’ of FIG. 8A, and FIG. 9 is a cross-sectional view taken along line Ⅱ-Ⅱ’ of FIG. 3.

Referring to FIGS. 8A, 8B, and 9, the semiconductor memory device 100b according to an embodiment may include the substrate 102 and the plurality of sub cell arrays SCA. The plurality of sub cell arrays SCA may be arranged in the second horizontal direction (e.g., Y-axis direction). The each sub cell array SCA may include the substrate 102, the plurality of word lines WL which are apart from the substrate 102 and are disposed on a main surface 102M of the substrate 102, the plurality of bit lines BL which extend in the vertical direction (e.g., Z-axis direction) from the main surface 102M of the substrate 102, the plurality of cell transistors CT which are disposed between the plurality of word lines WL and the plurality of bit lines BL, and the plurality of information storage elements SP which are respectively connected to the plurality of cell transistors CT. The cell transistor CT and the information storage element SP may configure (or form) the memory cell MC.

The substrate 102 may include, for example, silicon (Si), such as crystalline Si, single crystalline Si, or amorphous Si. In another example, the substrate 102 may include at least one compound semiconductor selected from among silicon germanium (SiGe), silicon carbide (SiC), gallium arsenide (GaAs), indium arsenide (InAs), indium phosphide (InP), and a semiconductor element such as germanium (Ge). In another example, the substrate 102 may include a silicon-on-insulator (SOI) substrate or a germanium-on-insulator (GeOI) substrate. For example, the substrate 102 may include a buried oxide (BOX) layer. The substrate 102 may include a conductive region, and, for example, may include an impurity-doped well or an impurity-doped structure.

The plurality of word lines WL may extend in the first horizontal direction (e.g., X-axis direction) on the substrate 102 and may be apart from one another in the vertical direction (e.g., Z-axis direction). The plurality of bit lines BL may extend in the vertical direction (e.g., Z-axis direction) from the substrate 102 and may be apart from one another in the first horizontal direction (e.g., X-axis direction). In FIG. 8A, it is illustrated that the plurality of bit lines BL extend in the vertical direction (e.g., Z-axis direction) and are apart from one another in the first horizontal direction (e.g., X-axis direction), but as shown in FIGS. 1 and 3, the plurality of bit lines BL may extend in the vertical direction (e.g., Z-axis direction) and may be apart from one another in the first horizontal direction (e.g., X-axis direction) and the second horizontal direction (e.g., Y-axis direction).

The cell transistor (e.g., single cell transistor) CT may be disposed between the word line (e.g., single word line) WL and the bit line (e.g., single bit line) BL. The information storage element SP may be connected to the cell transistor CT. The cell transistor CT and the information storage element SP may be sequentially arranged in the second horizontal direction (e.g., Y-axis direction) from the bit line BL connected to the cell transistor CT.

The word line WL may be adjacent to a semiconductor pattern 110. In some embodiments, the word line WL may surround the semiconductor pattern 110. A gate dielectric layer 132 may be disposed between the word line WL and the semiconductor pattern 110. The word line WL and the gate dielectric layer 132 may configure (or form) a word line structure WLS. The semiconductor pattern 110 and the word line structure WLS may configure (or form) the cell transistor CT.

The semiconductor pattern 110 may include the source region SD1, the drain region SD2, and the channel region CH disposed between the source region SD1 and the drain region SD2. The source region SD1 may be connected to the bit line BL, and the drain region SD2 may be connected to the information storage element SP. The source region SD1 may be referred to as a direct contact, and the drain region SD2 may be referred to as a buried contact.

The source region SD1, the channel region CH, and the drain region SD2 may be sequentially arranged in the second horizontal direction (e.g., Y-axis direction) or an opposite direction of the second horizontal direction (e.g., Y-axis direction) from the bit line BL. For example, two sub cell arrays SCA adjacent to each other in the second horizontal direction (e.g., Y-axis direction) may share bit lines BL between the two sub cell arrays SCA. Source regions SD1 of cell transistors CT included in each of the two sub cell arrays SCA may be connected to bit lines BL shared by the two sub cell arrays SCA. The source region SD1, the channel region CH, and the drain region SD2 of the cell transistor CT and the information storage element SP of each of the two sub cell arrays SCA may be arranged in directions (for example, a positive Y-axis direction or a negative Y-axis direction) opposite to each other from the shared bit lines BL. For example, the source region SD1, the channel region CH, and the drain region SD2 of the cell transistor CT and the information storage element SP of the sub cell array SCA connected to the bit line BL shared by the two sub cell arrays SCA may be sequentially arranged in the second horizontal direction (e.g., Y-axis direction), and the source region SD1, the channel region CH, and the drain region SD2 of the cell transistor CT and the information storage element SP of the other sub cell array SCA connected to the bit line BL may be sequentially arranged in an opposite direction of the second horizontal direction (e.g., Y-axis direction). For example, two memory cells MC may be disposed in the second horizontal direction (e.g., Y-axis direction) at the same vertical level, between a pair of bit lines BL sequentially arranged adjacent to each other in the second horizontal direction (e.g., Y-axis direction) among the plurality of bit lines BL.

In some embodiments, the semiconductor pattern 110 may include a material having an etch characteristic which is the same as or similar to that of the substrate 102. In some embodiments, the semiconductor pattern 110 may include the same material as that of the substrate 102. In some embodiments, the semiconductor pattern 110 may include Si. In some embodiments, the semiconductor pattern 110 may include a single crystalline semiconductor material. For example, the semiconductor pattern 110 may include single crystalline Si. In other some embodiments, the semiconductor pattern 110 may include a two-dimensional (2D) semiconductor material or an oxide semiconductor material.

Partial portions of the semiconductor pattern 110 and the word line WL corresponding to each other may overlap each other in the vertical direction (e.g., Z-axis direction). In some embodiments, the semiconductor pattern 110 may pass through the word line WL and may extend in the second horizontal direction (e.g., Y-axis direction). At least a portion of the channel region CH may overlap the word line WL in the vertical direction (e.g., Z-axis direction). In some embodiments, the channel region CH may include a portion passing through the word line WL. For example, the channel region CH may be a portion, overlapping the word line WL in the vertical direction (e.g., Z-axis direction), of the semiconductor pattern 110. In some embodiments, the channel region CH may be a portion, passing through the word line WL, of the semiconductor pattern 110. A length of the channel region CH in the second horizontal direction (e.g., Y-axis direction) may be equal to that of the word line WL in the second horizontal direction (e.g., Y-axis direction). A length of the source region SD1 in the second horizontal direction (e.g., Y-axis direction) may be equal to an interval between the word line WL and the bit line BL in the second horizontal direction (e.g., Y-axis direction).

The source region SD1 and the drain region SD2 of the semiconductor pattern 110 may be doped with a first impurity. In some embodiments, the channel region CH may be doped with a second impurity that is different from the first impurity. For example, the first impurity may allow each of the source region SD1 and the drain region SD2 to have a first conductivity type, and the second impurity may allow the channel region CH to have a second conductivity type which differs from the first conductivity type. In some embodiments, the first conductivity type may be n-type, and the second conductivity type may be p-type, but the disclosure is not limited thereto. For example, the first conductivity type may be p-type, and the second conductivity type may be n-type, but the disclosure is not limited thereto. When the first conductivity type is n-type, the first impurity may be phosphorus (P), arsenic (As), or antimony (Sb), and when the second conductivity type is p-type, the second impurity may be boron (B), aluminum (Al), gallium (Ga), or indium (In). For example, the source region SD1 and the drain region SD2 of the semiconductor pattern 110 may be doped with phosphorus (P).

The word line WL may surround a portion of the semiconductor pattern 110 with the gate dielectric layer 132 therebetween. For example, the gate dielectric layer 132 may cover an upper surface and a lower surface of a portion of the semiconductor pattern 110 and may cover both side surfaces of the semiconductor pattern 110 in the first horizontal direction (e.g., X-axis direction), and the word line WL may cover the gate dielectric layer 132 covering an upper surface and a lower surface of a portion of the semiconductor pattern 110 and covering the both side surfaces of the semiconductor pattern 110 in the first horizontal direction (e.g., X-axis direction).

In some embodiments, the word line WL may include a conductive barrier layer covering the gate dielectric layer 132 and a conductive fill layer covering the conductive barrier layer. The conductive barrier layer may include, for example, metal, conductive metal nitride, conductive metal silicide, or a combination thereof.

The gate dielectric layer 132 may include at least one material selected from among silicon oxide, a high-k dielectric material having a dielectric constant which is higher than that of silicon oxide, and a ferroelectric material. In some embodiments, the gate dielectric layer 132 may have a stack structure of a first dielectric layer including silicon oxide and a second dielectric layer including at least one material selected from among a high-k dielectric material and a ferroelectric material.

The bit line BL may include metal. For example, the bit line BL may include metal such as titanium (Ti), tantalum (Ta), molybdenum (Mo), ruthenium (Ru), tungsten (W), cobalt (Co), aluminum (Al), or nickel (Ni), conductive metal nitride such as titanium nitride (TiN), tantalum nitride (TaN), tungsten nitride (WN), ruthenium titanium nitride (RuTiN), titanium silicon nitride (TiSiN), tungsten silicon nitride (WSiN), or tantalum silicon nitride (TaSiN), metal silicide such as titanium silicide (TiSi), tungsten silicide (WSi), tantalum silicide (TaSi), cobalt silicide (CoSi), or nickel silicide (NiSi), or a combination thereof.

An isolation insulation layer 105 may be disposed between the substrate 102 and the bit line BL. The bit line BL may be disposed on the isolation insulation layer 105. The semiconductor memory device 100 may include a plurality of isolation insulation layers 105 corresponding to a plurality of bit lines BL. The isolation insulation layer 105 may electrically insulate the substrate 102 from the bit line BL. At least a portion of the isolation insulation layer 105 may be buried in the substrate 102. The isolation insulation layer 105 may be apart from the semiconductor pattern 110. In some embodiments, the isolation insulation layer 105 may include an insulating material including impurity. The impurity included in the isolation insulation layer 105 may be the same as impurity included in the source region SD1. For example, the isolation insulation layer 105 may include the first impurity. In some embodiments, the isolation insulation layer 105 may include phosphosilicate glass (PSG) or borosilicate (BSG). For example, when the source region SD1 has an n-type as the first conductivity type, the isolation insulation layer 105 may include PSG. For example, when the source region SD1 has a p-type as the first conductivity type, the isolation insulation layer 105 may include BSG.

In some embodiments, the information storage element SP may be a capacitor structure 150 which includes a first electrode 152, a second electrode 156, and a capacitor dielectric layer 154 disposed between the first electrode 152 and the second electrode 156. The capacitor structure 150 may include the first electrode 152 which is connected to the drain region SD2 of the semiconductor pattern 110 and extends in the second horizontal direction (e.g., Y-axis direction), the capacitor dielectric layer bcovering the first electrode 152, and the second electrode 156 covering the capacitor dielectric layer 154. The second electrode 156 may be connected to the ground wiring PP illustrated in FIG. 1, or may be a portion of the ground wiring PP. The first electrode 152 and the second electrode 156 may be respectively referred to as a lower electrode and an upper electrode. The capacitor dielectric layer 154 may be disposed between the first electrode 152 and the second electrode 156.

The first electrode 152 may include metal, conductive metal nitride, conductive metal silicide, or a combination thereof. The capacitor dielectric layer 154 may include at least one material selected from among a ferroelectric material and a high-k dielectric material having a dielectric constant which is higher than that of silicon oxide. For example, the capacitor dielectric layer 154 may include at least one of metal oxide or a dielectric material of a perovskite structure. The second electrode 156 may include, for example, doped silicon, ruthenium (Ru), ruthenium oxide (RuO), platinum (Pt), platinum oxide (PtO), iridium (Ir), iridium oxide (IrO), strontium ruthenium oxide (SRO: SrRuO), barium strontium ruthenium oxide (BSRO: (Ba,Sr)RuO), calcium ruthenium oxide (CRO: CaRuO), barium ruthenium oxide (BaRuO), lanthanum strontium cobalt oxide La(Sr,Co)O, titanium (Ti), titanium nitride (TiN), tungsten (W), tungsten nitride (WN), tantalum (Ta), tantalum nitride (TaN), titanium aluminum nitride (TiAlN), titanium silicon nitride (TiSiN), tantalum aluminum nitride (TaAlN), tantalum silicon nitride (TaSiN), or a combination thereof. In FIG. 3, it is illustrated that the plurality of information storage elements SP are apart from one another, but the disclosure is not limited thereto. In some embodiments, when the plurality of information storage elements SP are a plurality of capacitor structures 150, a plurality of second electrodes 156 of the plurality of capacitor structures 150 included in the sub cell array SCA may be connected to each other to configure (or form) a single body. In some embodiments, in a case where the plurality of information storage elements SP are the plurality of capacitor structures 150, when a plurality of capacitor structures 150 included in each of a pair of sub cell arrays SCA adjacent to each other in the second horizontal direction (e.g., Z-axis direction) are adjacent to each other to face each other, a plurality of second electrodes 156 of the plurality of capacitor structures 150 included in each of the pair of sub cell arrays SCA may be connected to each other to configure (or form) a single body.

The plurality of word line pads WLP apart from each other in the vertical direction (e.g., Z-axis direction) may be disposed in the pad region WPR. The word line contact WLC may be connected to the word line pad WLP. The word line contact WLC may include metal, conductive metal nitride, conductive metal silicide, or a combination thereof.

An insulation structure 190 may cover the sub cell array SCA, the word line pad WLP, and the word line contact WLC, on the substrate 102. The plurality of word lines WL and the plurality of word line contacts WLC may surround the insulation structure 190. In some embodiments, the insulation structure 190 may be formed of a single layer or a multilayer.

In some embodiments, the insulation structure 190 may include silicon oxide, silicon nitride, a low-k dielectric material, or a combination thereof. The low-k dielectric material may be a material having a dielectric constant which is lower than that of silicon oxide, and, for example, may include phosphosilicate glass (PSG), borophosphosilicate glass (BPSG), fluorosilicate glass (FSG), organosilicate glass (OSG), spin-on-glass (SOG), spin-on-polymer, or a combination thereof. In some embodiments, the insulation structure 190 may include an ultra-low k (ULK) layer having an ultra-low dielectric constant K of about 2.2 to about 2.4. The ULK layer may include SiOC or SiCOH.

Referring to FIG. 9, the width W1 of the word line pad WLP in the first horizontal direction (e.g., X-axis direction) may be less than the width W2 of the word line pad WLP in the second horizontal direction (e.g., Y-axis direction). Each of the plurality of word line pads WLP may be disposed at the same vertical level as a corresponding pair among the plurality of word lines WL. For example, the word line pad WLP may contact a lower surface or an upper surface of the corresponding pair among the plurality of word lines WL.

The insulation structure 190 may surround the plurality of word lines WL. The insulation structure 190 may include a first insulation structure 190(A) and a second insulation structure 190(B), which are stacked in the vertical direction (e.g., Z-axis direction). In an embodiment, the first insulation structure 190(A) may be disposed between word lines WL apart from each other in a horizontal direction. The second insulation structure 190(B) may be disposed between word lines WL apart from each other in a horizontal direction. In an embodiment, the word line pad WLP may be disposed between second insulation layers 190(B) adjacent to each other in the vertical direction (e.g., Z-axis direction), and unlike the arrangement shown in FIG. 9, in another embodiment, at least a portion of the first insulation structure 190(A) may be disposed on a lower surface and/or an upper surface of the word line pad WLP.

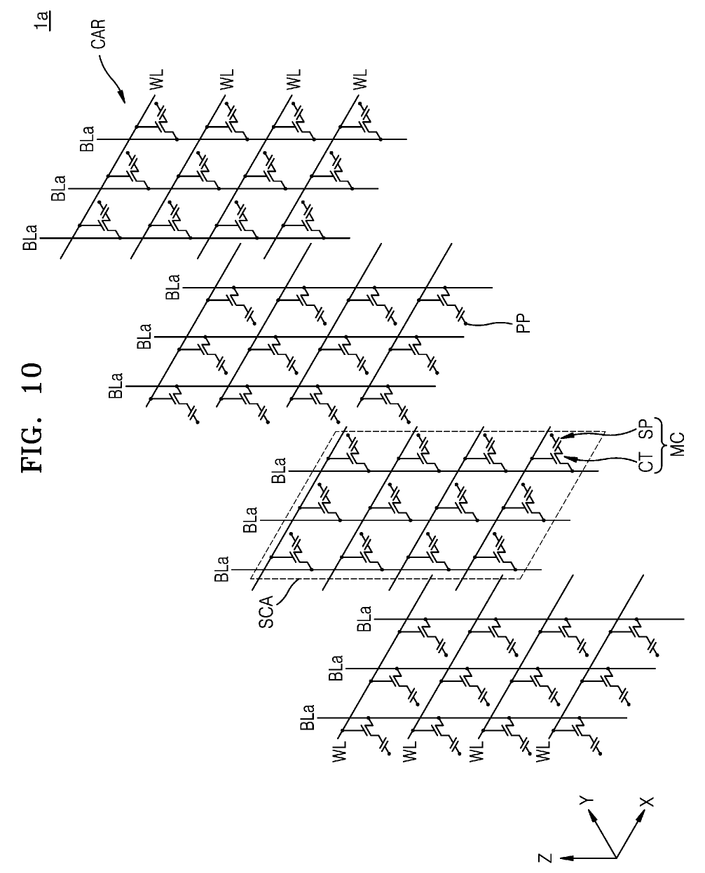

FIG. 10 is an equivalent circuit diagram illustrating a memory cell array 1a of a semiconductor memory device according to an embodiment.

Referring to FIG. 10, the memory cell array 1a of the semiconductor memory device according to an embodiment may include the plurality of sub cell arrays SCA. Each of the plurality of sub cell arrays SCA may include the plurality of bit lines BLa, the plurality of word lines WL, and the plurality of memory cells MC. Each of the plurality of memory cells MC may include the cell transistor CT and the information storage element SP. The cell transistor (e.g., single cell transistor) CT may be disposed between the word line (e.g., single word line) WL and the bit line (e.g., single bit line) BLa. The plurality of sub cell arrays SCA may be arranged in the second horizontal direction (e.g., Y-axis direction).

The plurality of word lines WL may extend in the first horizontal direction (e.g., X-axis direction). Word lines WL of the sub cell array (e.g., single sub cell array) SCA may be apart from one another in the vertical direction (e.g., Z-axis direction). The bit line BLa may extend in the vertical direction (e.g., Z-axis direction). The bit lines BLa of the sub cell array (e.g., single sub cell array) SCA may be apart from one another in the first horizontal direction (e.g., X-axis direction).

The gate of the cell transistor CT may be connected to the word line WL, and the source region of the cell transistor CT may be connected to the bit line BLa. The information storage element SP may be connected to the drain region of the cell transistor CT.

In some embodiments, the source region and the drain region of the cell transistor CT and the information storage element SP may be arranged in the second horizontal direction (e.g., Y-axis direction) or an opposite direction of the second horizontal direction (e.g., Y-axis direction) from the bit line BLa connected to the source region of the cell transistor CT. The source region and the drain region of the cell transistor CT, connected to each of the two bit lines BLa adjacent to each other in the second horizontal direction (e.g., Y-axis direction), and the information storage element SP may be arranged in directions opposite to each other. For example, the source region and the drain region of the cell transistor CT, connected to one bit line BLa among the two bit lines BLa adjacent to each other in the second horizontal direction (e.g., Y-axis direction), and the information storage element SP may be sequentially arranged in the second horizontal direction (e.g., Y-axis direction), and the source region and the drain region of the cell transistor CT, connected to the other bit line BLa, and the information storage element SP may be arranged in a direction opposite to the second horizontal direction (e.g., Y-axis direction).

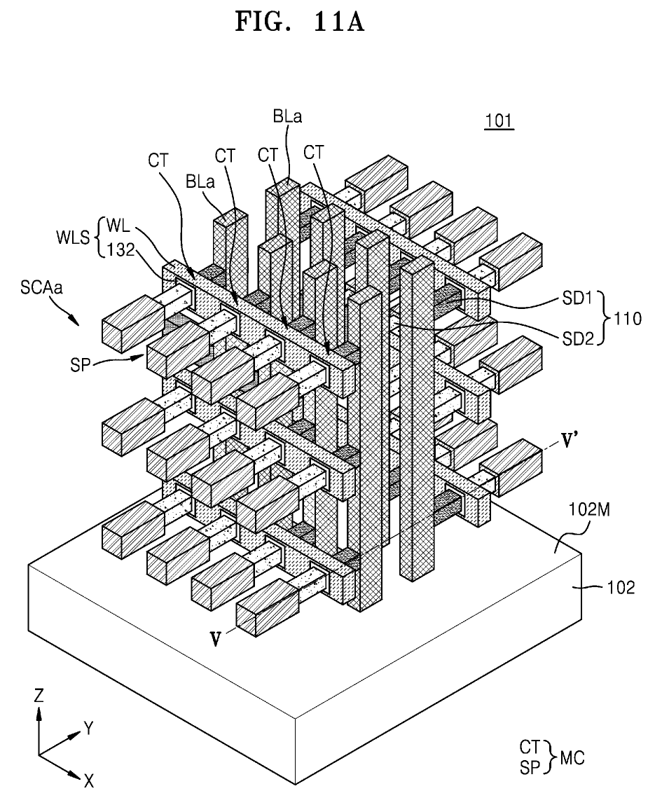

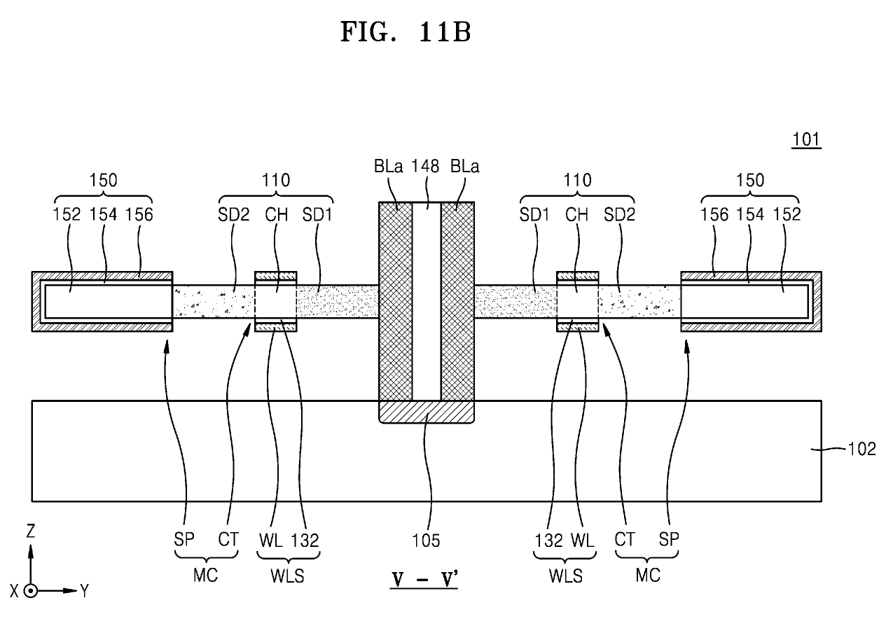

FIG. 11A is a perspective view illustrating a portion of a semiconductor memory device 101 according to an embodiment, and FIG. 11B is a cross-sectional view illustrating a portion of the semiconductor memory device 101 according to an embodiment. In detail, FIG. 11B is a cross-sectional view taken along line Ⅴ-Ⅴ’ of FIG. 11A.

Referring to FIGS. 11A and 11B, the semiconductor memory device 101 may include the substrate 102 and the plurality of sub cell arrays SCAa. The plurality of sub cell arrays SCAa may be arranged in the second horizontal direction (e.g., Y-axis direction). The sub cell array SCAa may include the substrate 102, the plurality of word lines WL which are apart from the main surface 102M of the substrate 102 and are disposed on the substrate 102, the plurality of bit lines BLa which extend in the vertical direction (e.g., Z-axis direction) from the main surface 102M of the substrate 102, the plurality of cell transistors CT which are disposed between the plurality of word lines WL and the plurality of bit lines BLa, and the plurality of information storage elements SP which are respectively connected to the plurality of cell transistors CT. The plurality of cell transistors CT and the plurality of information storage elements SP may configure (or form) the plurality of memory cells MC.

The plurality of word lines WL may extend in the first horizontal direction (e.g., X-axis direction) on the substrate 102 and may be apart from one another in each of the second horizontal direction (e.g., Y-axis direction) and the vertical direction (e.g., Z-axis direction). The plurality of bit lines BLa may extend in the vertical direction (e.g., Z-axis direction) from the substrate 102 and may be apart from one another in each of the first horizontal direction (e.g., X-axis direction) and the second horizontal direction (e.g., Y-axis direction).

The cell transistor (e.g., single cell transistor) CT may be disposed between the word line (e.g., single word line) WL and the bit line (e.g., single bit line) BLa. The information storage element SP may be connected to the cell transistor CT. The cell transistor CT and the information storage element SP may be sequentially arranged in the second horizontal direction (e.g., Y-axis direction) or an opposite direction of the second horizontal direction (e.g., Y-axis direction) from the bit line BLa connected to the cell transistor CT.

The source region SD1, the channel region CH, and the drain region SD2 may be sequentially arranged in the second horizontal direction (e.g., Y-axis direction) or an opposite direction of the second horizontal direction (e.g., Y-axis direction) from the bit line BLa. Two sub cell arrays SCAa adjacent to each other in the second horizontal direction (e.g., Y-axis direction) may not share bit lines BLa. The source region SD1, the channel region CH, and the drain region SD2 of the cell transistor CT, connected to each of the two bit lines BLa adjacent to each other in the second horizontal direction (e.g., Y-axis direction), and the information storage element SP may be arranged in directions opposite to each other.

For example, the source region SD1, the channel region CH, and the drain region SD2 of a cell transistor CT, connected to the bit line (e.g., single bit line) BLa among the two bit lines BLa adjacent to each other in the second horizontal direction (e.g., Y-axis direction), and the information storage element SP may be sequentially arranged in the second horizontal direction (e.g., Y-axis direction), and the source region SD1, the channel region CH, and the drain region SD2 of the cell transistor CT, connected to the other bit line BLa, and the information storage element SP may be arranged in a direction opposite to the second horizontal direction (e.g., Y-axis direction).

The isolation insulation layer 105 may be disposed between the substrate 102 and the bit line BLa. The bit line BLa may be apart from the substrate 102 with the isolation insulation layer 105 therebetween. The isolation insulation layer 105 may electrically insulate the substrate 102 from the bit line BLa. At least a portion of the isolation insulation layer 105 may be buried in the substrate 102. The isolation insulation layer 105 may be apart from the semiconductor pattern 110. For example, an upper surface of the isolation insulation layer 105 may be disposed at a vertical level which is lower than a lower surface of a lowermost semiconductor pattern 110. The upper surface of the isolation insulation layer 105 may be disposed at a vertical level which is equal to or higher than an upper surface of the substrate 102.

A pair of bit lines BLa adjacent to each other in the second horizontal direction (e.g., Y-axis direction) may be disposed on an isolation insulation layer 105. The pair of bit lines BLa disposed on the isolation insulation layer 105 may be apart from each other with the insulation structure 148 therebetween. The pair of bit lines BLa adjacent to each other in the second horizontal direction (e.g., Y-axis direction) and an insulation structure 148 filling a region between the pair of bit lines BLa may be disposed on the isolation insulation layer 105. The sum of a width of the pair of bit lines BLa adjacent to each other in the second horizontal direction (e.g., Y-axis direction) and a width of the insulation structure 148 filling the region between the pair of bit lines BLa, in the second horizontal direction (e.g., Y-axis direction), may be substantially equal to a width of the isolation insulation layer 105 in the second horizontal direction (e.g., Y-axis direction).

In some embodiments, the information storage element SP may be the capacitor structure 150 which includes the first electrode 152, the second electrode 156, and the capacitor dielectric layer 154 disposed between the first electrode 152 and the second electrode 156. The capacitor structure 150 may include the first electrode 152 which is connected to the drain region SD2 of the semiconductor pattern 110 and extends in the second horizontal direction (e.g., Y-axis direction), the capacitor dielectric layer 154 covering the first electrode 152, and the second electrode 156 covering the capacitor dielectric layer 154. The second electrode 156 may be connected to the ground wiring PP illustrated in FIG. 10, or may be a portion of the ground wiring PP.

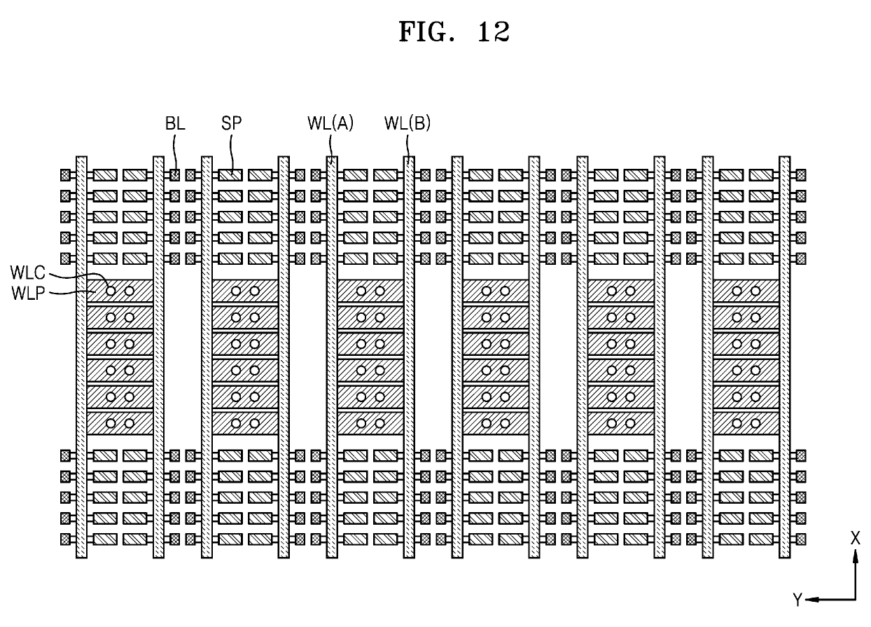

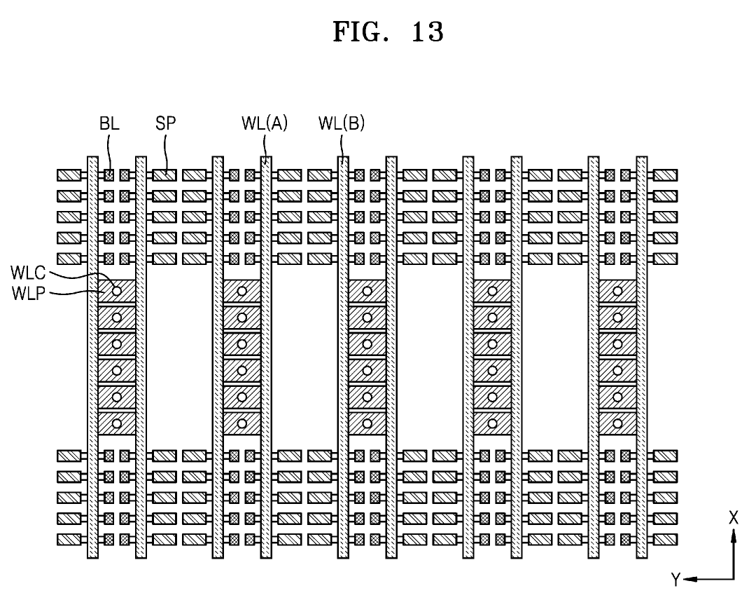

FIG. 12 is a plan view illustrating the arrangement of a semiconductor memory device according to an embodiment, and FIG. 13 is a plan view illustrating the arrangement of a semiconductor memory device according to an embodiment. In FIGS. 12 and 13, the same reference numerals as FIG. 7A may denote substantially the same elements, and thus, redundant descriptions may be omitted, and the difference therebetween will be described below.

Referring to FIG. 12, the plurality of bit lines BLa may include bit line columns which are the bit lines BLa arranged apart from one another to configure (or form) a column in the first horizontal direction (e.g., X-axis direction), and the bit line columns may be arranged apart from one another in the second horizontal direction (e.g., Y-axis direction). In a plan view, each of the bit line columns may not overlap the word line pad WLP disposed between the first word line WL(A) and the second word line WL(B) in the first horizontal direction (e.g., X-axis direction).

Referring to FIG. 13, the plurality of bit lines BLa may include the bit line columns which are the bit lines BLa arranged apart from one another to configure (or form) a column in the first horizontal direction (e.g., X-axis direction), and the bit line columns may be arranged apart from one another in the second horizontal direction (e.g., Y-axis direction). In a plan view, each of the bit line columns may overlap the word line pad WLP disposed between the first word line WL(A) and the second word line WL(B) in the first horizontal direction (e.g., X-axis direction). In a plan view, each of the bit line columns may be disposed between the first word line WL(A) and the second word line WL(B).

FIGS. 14A to 14D are cross-sectional views for describing a method of manufacturing a semiconductor memory device, according to an embodiment and illustrate a cross-sectional surface of portion IV of FIG. 4. In FIGS. 14A to 14D, the same reference numerals as FIG. 3 may denote substantially the same elements, and thus, redundant descriptions may be omitted, and a method of manufacturing the semiconductor memory 100 device will be briefly described.

The method of manufacturing the semiconductor memory device 100 according to an embodiment may include an operation of forming the substrate (e.g., 102 of FIG. 8A) including the stack region (e.g., STR of FIG. 3) and the pad region (e.g., WPR of FIG. 3) arranged in the first horizontal direction (e.g., X-axis direction in FIG. 3), an operation of forming the first word line stack (e.g., WLS(A) of FIG. 3), the second word line stack (e.g., WLS(B) of FIG. 3), the plurality of bit lines (e.g., BL of FIG. 3), and the plurality of memory cells (e.g., MC of FIG. 3) disposed in the stack region (e.g., STR of FIG. 3), on the substrate (e.g., 102 of FIG. 8A), and an operation of forming the plurality of word line contacts (e.g., WLC of FIG. 3) extending in the vertical direction (e.g., Z-axis direction) between the first word line stack (e.g., WLS(A) of FIG. 3) and the second word line stack (e.g., WLS(B) of FIG. 3) in the pad region (e.g., WPR of FIG. 3) and the plurality of word line pads (e.g., WLP of FIG. 3) which have different vertical levels and are apart from one another in the first horizontal direction (e.g., X-axis direction) between the first word line stack (e.g., WLS(A) of FIG. 3) and the second word line stack (e.g., WLS(B) of FIG. 3).

Referring to FIG. 14A, the first word line stack WLS(A) and the second word line stack WLS(B) may be formed on the substrate 102, and then, the through hole TH may be formed in the insulation structure 190 surrounding the first word line stack WLS(A) and the second word line stack WLS(B). The insulation structure 190 may include the first insulation structure 190(A) and the second insulation structure 190(B), which are stacked in the vertical direction (e.g., Z-axis direction). The through hole TH may be provided in plurality. The plurality of through holes TH may be formed between the first word line stack WLS(A) and the second word line stack WLS(B). FIGS. 14A to 14D illustrate a process of forming the word line pad WLP, and vertical levels of lower surfaces of the plurality of through holes TH may be equal to one another as shown in FIG. 14A. A lower surface of the through hole TH formed at a position at which the word line pad WLP is formed and a lower surface of a through hole TH formed at a position, at which another word line pad WLP is formed, may have different vertical levels.

Referring to FIGS. 14A to 14D, an empty space may be formed by removing, through the through hole TH, at least a portion of the first insulation structure 190(A) under the through hole TH. The word line pad WLP may be formed by implanting a material, which is for forming the word line pad WLP, into the empty space through the through hole TH. Subsequently, the word line contact WLC may be formed by implanting a material, which is for forming the word line contact WLC, into the through hole TH, and then, the contact connection wiring CCL may be formed on the word line contact WLC.

Hereinabove, embodiments have been described in the drawings and the specification. Embodiments have been described by using the terms described herein, but this has been merely used for describing the disclosure and has not been used for limiting a meaning or limiting the scope of the disclosure defined in the following claims. Therefore, it may be understood by those of ordinary skill in the art that various modifications and other equivalent embodiments may be implemented from the disclosure. Accordingly, the spirit and scope of the disclosure may be defined based on the spirit and scope of the following claims.

While the disclosure has been particularly shown and described with reference to embodiments thereof, it will be understood that various changes in form and details may be made therein without departing from the spirit and scope of the following claims.

What is claimed is:

1. A semiconductor memory device comprising:
a substrate comprising a stack region and a pad region arranged in a first horizontal direction;
a first word line and a second word line at a same vertical level and extending in the first horizontal direction in the stack region and the pad region, the first word line and the second word line spaced apart in a second horizontal direction intersecting the first horizontal direction;
a plurality of bit lines extending in a vertical direction in the stack region and spaced apart in the first horizontal direction;
a plurality of memory cells in the stack region;
a word line pad between the first word line and the second word line in the pad region; and
a word line contact extending in the vertical direction on the word line pad.

2. The semiconductor memory device of claim 1, wherein the word line pad is configured to be electrically connected to the first word line and the second word line.

3. The semiconductor memory device of claim 1, wherein the word line contact comprises a first contact portion and a second contact portion arranged in the second horizontal direction on the word line pad.

4. The semiconductor memory device of claim 3, further comprising:
a contact connection wiring connecting the first contact portion to the second contact portion and extending in the second horizontal direction.

5. The semiconductor memory device of claim 1, wherein a width of the word line pad in the second horizontal direction is equal to a distance between the first word line and the second word line in the second horizontal direction.

6. The semiconductor memory device of claim 1, wherein a width of the word line pad in the first horizontal direction is less than a width of the word line pad in the second horizontal direction.

7. The semiconductor memory device of claim 1, wherein the stack region comprises a first stack region adjacent to a first side of the pad region in the first horizontal direction and a second stack region adjacent to a second side of the pad region in the first horizontal direction, and
each of the first word line and the second word line extends to the first stack region, the pad region, and the second stack region.

8. The semiconductor memory device of claim 1, wherein each of the plurality of memory cells comprises a cell transistor and an information storage element, and
wherein the cell transistor comprises a semiconductor pattern extending in the second horizontal direction from each of the plurality of bit lines and at least one of the first word line and the second word line.

9. The semiconductor memory device of claim 8, wherein the word line pad in the pad region overlaps the information storage element in the stack region in the first horizontal direction.

10. The semiconductor memory device of claim 8, wherein the word line pad in the pad region overlaps the plurality of bit lines in the stack region in the first horizontal direction.

11. The semiconductor memory device of claim 1, wherein a first side of the word line pad in the second horizontal direction contacts the first word line, and a second side of the word line pad in the second horizontal direction contacts the second word line.

12. A semiconductor memory device comprising:
a substrate comprising a stack region and a pad region arranged in a first horizontal direction;
a first word line stack comprising a plurality of first word lines each extending in the first horizontal direction in the stack region and the pad region and stacked in a vertical direction;
a second word line stack spaced apart from the first word line stack in a second horizontal direction intersecting the first horizontal direction and comprising a plurality of second word lines each extending in the first horizontal direction in the stack region and the pad region and stacked in the vertical direction;
a plurality of bit lines extending in the vertical direction in the stack region and spaced apart in the first horizontal direction; and
a plurality of word line pads between the first word line stack and the second word line stack in the pad region and spaced apart in the vertical direction and the first horizontal direction.

13. The semiconductor memory device of claim 12, wherein the plurality of word line pads are arranged in a row in the first horizontal direction.

14. The semiconductor memory device of claim 12, wherein each of the plurality of word line pads is configured to be electrically connected to a selected first word line among the plurality of first word lines and a selected second word line among the plurality of second word lines, the selected first word line and the selected second word line being at a same vertical level.

15. The semiconductor memory device of claim 12, further comprising:
a plurality of word line contacts on the plurality of word line pads in the pad region; and
a plurality of sub word line drivers configured to be electrically connected to the plurality of word line contacts.

16. The semiconductor memory device of claim 15, wherein the plurality of word line contacts each comprise a plurality of contact portions spaced apart in the second horizontal direction on a selected word line pad among the plurality of word line pads.

17. The semiconductor memory device of claim 12, further comprising:
a third word line stack adjacent to the second word line stack in the second horizontal direction and comprising a plurality of third word lines each extending in the first horizontal direction in the stack region and the pad region and stacked in the vertical direction,
wherein the plurality of bit lines are horizontally between the second word line stack and the third word line stack.

18. The semiconductor memory device of claim 12, wherein the plurality of bit lines are horizontally between the first word line stack and the second word line stack.

19. The semiconductor memory device of claim 12, wherein a number of the plurality of word line pads is equal to a number of the plurality of first word lines included in the first word line stack.

20. A semiconductor memory device comprising:
a substrate comprising a stack region and a pad region arranged in a first horizontal direction;
a first word line stack comprising a plurality of first word lines each extending in the first horizontal direction in the stack region and the pad region and stacked in a vertical direction;
a second word line stack spaced apart from the first word line stack in a second horizontal direction intersecting the first horizontal direction and comprising a plurality of second word lines each extending in the first horizontal direction in the stack region and the pad region and stacked in the vertical direction;
a plurality of bit lines extending in the vertical direction in the stack region and spaced apart in the first horizontal direction;
a plurality of memory cells in the stack region and comprising a cell transistor and an information storage element;
a plurality of word line pads arranged in the first horizontal direction at different vertical levels, between the first word line stack and the second word line stack in the pad region; and
a plurality of word line contacts extending in the vertical direction on the plurality of word line pads, each word line contact comprising a plurality of contact portions spaced apart from each other in the second horizontal direction,
wherein a width of each of the plurality of word line pads in the first horizontal direction is less than a width of each word line pad in the second horizontal direction.
